(19) United States
(12) Patent Application Publication
(10) Pub. No.: US 2011/0079709 A1
(43) Pub. Date: Apr. 7, 2011

(54) WIDE BAND SENSOR

(76) Inventor: Kristy A. Campbell, Boise, ID (US)

(21) Appl. No.: 12/574,897

(22) Filed: Oct. 7, 2009

(51) Int. Cl. H01L 27/14; H01L 31/02

(52) U.S. Cl. 250/214 R; 257/431; 257/E27.122; 257/E31.001

(57) ABSTRACT

A sensor and method of sensing is disclosed. The sensor is designed with a number of layers that are each able to sense a range of electromagnetic radiation. The sensor has two terminals for measuring the output signal of the sensor. The output signal of the sensor can be separated to identify the contributions to the output signal from each layer in order to determine the layer(s) that detected electromagnetic radiation. An array of sensors may be fabricated to increase the number of samples taken.

### BACKGROUND

The present application relates generally to a sensing apparatus and methods for sensing the wavelength and/or the intensity of electro-magnetic radiation (“EMR”). More specifically, the application relates a single sensor that may concurrently sense multiple regions of the electromagnetic spectrum and/or may be adapted to be sensitive to selected regions of electromagnetic spectrum.

Often within this disclosure, EMR is generally referred to as light, even though the region of electromagnetic spectrum being discussed may not be human-visible. When greater detail is called for, more specific terms are employed.

Devices that absorb electro-magnetic radiation are used in many applications. Common devices include solar cells, visible light detectors, and infrared detectors. Solar cells are generally designed to absorb light of specific wavelengths from the sun's electromagnetic spectrum. Both visible light sensors and infrared sensors typically absorb only one distinct, continuous region of electromagnetic spectrum, such as visible light or infrared EMR.

Historically, solar cells have had low efficiencies due to, among other things, poor absorption of the incident light. Low energy light typically passes through the solar cell, unabsorbed, while much of the higher energy light is converted into heat, rather than electricity. Only the energy of a small region of the electromagnetic spectrum is absorbed by the solar cell, and accordingly, only a small amount of the total incident EMR from the sun is converted into electricity.

To improve absorption, and thus efficiency, solar cells that utilize multi-layer designs have been created. For example, “tandem” (two layer) solar cells are designed to enhance absorption by using a first layer to absorb relatively high energy light and a second layer to absorb relatively lower energy light that has passed through the first layer.

Generally, tandem solar cells use two different materials that are selected to absorb two different regions of electromagnetic spectrum. While absorption of a broad region of spectrum may be the goal, it is the nature of materials that are suitable for use with solar cells (i.e. suitable for creating an electric current) to absorb small regions of the electromagnetic spectrum.

When energy from light is absorbed by a layer of a solar cell, electrons are excited to the conduction band or conduction extended states. The intensity of the light (number of photons) incident upon the solar cell is directly proportional to the number of excited electrons. These electrons may then be influenced to move through the material with one or more additional circuits that are connected to each layer of the solar cell. In this way, movement of electrons (current) is created with the absorbed photon energy, and may be harnessed to power electric devices. A solar cell is not intended for and is not enabled to measure characteristics of the incident light.

Another common device that interacts with EMR is a visible light sensor, such as a device that contains silicon photodiodes (e.g. CMOS imager), which are sensitive to a region of electromagnetic spectrum approximately corresponding to the wavelength range of visible light (about 400 nanometers (“nm”) to about 700 nm).

Additionally, infrared (“IR”) sensors are also common. IR sensors are typically made from a single material that is sensitive to a defined region of electromagnetic spectrum within the wavelength range of IR light (about 700 nm to about 100 micrometers (“μm”)). The region of sensitivity depends on the material. For example, lead sulfide (PbS) can be used to make an IR sensor that is sensitive to a spectral range of about 1 μm to about 3.2 μm, lead selenide (PbSe) can be used to make an IR sensor that is sensitive to a spectral range of about 1.5 μm to about 5.2 μm, and Indium Gallium Arsenide can be used to make an IR sensor that is sensitive to a spectral range of about 0.7 μm to about 2.6 μm. Many other materials may be suitable for making an IR sensor, as would be apparent to one of ordinary skill in the art given the benefit of this disclosure.

As with solar cells, the output of visible light sensors and IR sensors is an electric current that can be measured and correlated with a baseline to measure the intensity of EMR incident upon the sensor.

Generally, to measure one region of electromagnetic spectrum, one sensor is used. To measure a large region of electromagnetic spectrum, many sensors that each measure a small region of electromagnetic spectrum may be used to measure the larger region of electromagnetic spectrum. Using many sensors in combination requires additional circuitry and connections for each additional sensor, adding complexity, and creating a piecemeal approach to solving the problem of measuring large regions of electromagnetic spectrum.

### SUMMARY

As discussed above, sensors that are sensitive to a specific region of electromagnetic spectrum are common, but sensors that are sensitive to multiple individual regions of electromagnetic spectrum are not common. Further, sensors that can be adapted to sense different regions of electromagnetic spectrum are not common. It is desirable to create a wide band sensor that may be sensitive to a wide region of electromagnetic spectrum. It is desirable to create an adaptive sensor that may be used to detect a selected region of electromagnetic spectrum among a plurality of selectable regions of electromagnetic spectrum. It is desirable to create an adaptive wide band sensor that may be adapted to be sensitive to multiple selected regions of electromagnetic spectrum. Additionally, it is desirable to create a wide band sensor with only two terminals. The present disclosure is directed toward overcoming, or at least reducing the effects of, one or more of the issues set forth above.

An electromagnetic radiation sensing system may have a signal separation module connected to a sensor. The sensor may comprise a first terminal, a second terminal, and a plurality of layers formed on a substrate. The sensor may have a first layer and a last layer. The first layer may be connected to the first terminal and the last layer may be connected to the second terminal. Each layer may be coupled to another layer to form an interface. Each layer may be sensitive to a distinct range of wavelengths of electromagnetic radiation. Each layer may have a distinct carrier recombination rate. The sensor may be configured to generate an output signal at the first and second terminals in response to electro-magnetic radiation incident upon a surface of the sensor. The signal separation module may be configured to determine the individual contribution from each of the plurality of layers to the output signal.

The electromagnetic sensing system may further comprise one or more interleaving layers positioned between the first layer and the last layer. Each interleaving layer may be coupled to two or more other adjacent layers forming interfaces. Each interleaving layer may be sensitive to a distinct range of wavelengths of electromagnetic radiation and may have a distinct carrier recombination rate.

The electromagnetic sensing system may have a characteristic measurement circuit connected to the first and second terminals which may measure capacitance, inductance, charge, voltage, resistance, or current. The signal separation module may be connected to the sensor through the characteristic measurement circuit.

The layers of the electromagnetic sensing system may be positioned in a stacked arrangement and may be configured to be substantially transparent to electromagnetic radiation of lower energy than a range of wavelengths of electromagnetic radiation to which the layer is sensitive. The sensor of the electromagnetic sensing system may be configured to collect charge at one or more interfaces.

A sensor may comprise a first terminal, a second terminal, and a plurality of layers formed on a substrate. The sensor may have a first layer, a second layer, and a last layer. The first layer may be connected to the first terminal and the last layer may be connected to the second terminal. Each layer may be coupled to another layer to form an interface. Each layer may be sensitive to a distinct range of wavelengths of electromagnetic radiation. Each layer may have a distinct carrier recombination rate.

The one or more layers of the of the electromagnetic sensing system may include lead telluride, lead sulfide, indium gallium arsenide, lead selenide, indium antimonide, mercury cadmium telluride, silicon, copper indium selenide, or copper indium sulfide. An interface of the electromagnetic sensing system may form a Schottky barrier. The layers of the electromagnetic sensing system may each be sensitive to a distinct, non-overlapping range of wavelengths.

A sensor array according to this disclosure may comprise a plurality of sensors arranged in an array across a substrate. Each of the plurality of sensors may be connected to one or more characteristic measurement circuits. The sensors may comprise a first terminal, a second terminal, and a plurality of layers. The sensors may have a first layer and a last layer, which may be coupled to another layer to form an interface. Each layer may be sensitive to a distinct range of wavelengths of electromagnetic radiation. Each layer may have a distinct carrier recombination rate. The first layer may be connected to the first terminal and the last layer may be connected to the second terminal.

The sensors or the sensor array may be configured to be substantially the same. The sensor array may further comprising a micro-lens array. The sensor array may be configured to be used with a set of optics.

A method of detecting a range of wavelengths of electro-magnetic radiation, the range having a plurality of distinct sub-ranges may comprise exposing a sensor to electro-magnetic radiation, measuring one or more characteristics of the sensor over time to generate an output signal at the first terminal and the second terminal, and determining the individual contribution to the output signal from each of the plurality of layers. The sensor may have a plurality of layers. Each layer may be sensitive to a distinct sub-range of wavelengths of electro-magnetic radiation. The sensor may have a first terminal connected to a first layer and may have a second terminal connected to a last layer.

The method may further comprise applying a voltage bias to the sensor across the first terminal and the second terminal. The method may further comprise removing the voltage bias prior to measuring one or more characteristics of the sensor over time, which may generate an output signal. The method may further comprise outputting the individual contributions that are determined. The method may further comprise outputting a selected portion of the determined individual contributions. The method may further comprise generating carriers in a layer when the sensor is exposed to electro-magnetic radiation. The method may further comprise allowing the generated carriers to recombine within the same layer in which they were generated. The method may further comprise collecting the carriers at an interface.

These and other embodiments of the present application will be discussed more fully in the description. The features, functions, and advantages can be achieved independently in various embodiments of the claimed invention, or may be combined in yet other embodiments.

### BRIEF DESCRIPTION OF FIGURES

FIG. 1 is a cut away block diagram of a two-layer stacked wide band sensor connected to a characteristic measurement circuit and a signal separation module;

FIG. 2 is a cut away block diagram of an n-layer stacked wide band sensor;

FIG. 3 is a cut away block diagram of a two-layer planar wide band sensor;

FIG. 4 is a top view of a portion of an adaptive focal plane array;

FIG. 5 is a graph of capacitance change over time.

Like reference numbers and designations in the various drawings indicate like elements.

### DETAILED DESCRIPTION

In the following description, reference is made to the accompanying drawings that form a part thereof, and in which is shown by way of illustration specific exemplary embodiments in which the invention may be practiced. These embodiments are described in sufficient detail to enable those skilled in the art to practice the invention, and it is to be understood that modifications to the various disclosed embodiments may be made, and other embodiments may be utilized, without departing from the spirit and scope of the present invention. The following detailed description is, therefore, not to be taken in a limiting sense.

It will be understood by one of ordinary skill in the art that energy, wavelength, and frequency often may be used interchangeably when discussing light. The relationship of energy, wavelength, and frequency can be seen in the Einstein's equation for photon energy,

E=hf=hc/λ

In which E is photon energy in electron-Volts (“eV”), h is Planck's constant, f is frequency in Hertz (“Hz”), c is the speed of light in meters per second (“m/s”), and λ is wavelength in micrometers (“μm”) or nanometers (“nm”), as appropriate. As would also be apparent to one of ordinary skill in the art, other units may be used when describing characteristics of EMR.

Einstein's equation for photon energy provides that a particle of light (photon) that is very energetic will have a high frequency and a short wavelength. The inverse is also true; a low energy photon will have low frequency and long wavelength. For example, light from the violet portion of the visible light spectrum has a wavelength of about 400 nanometers (“nm”), a frequency of about 7.5×10¹⁴ Hertz (“Hz”), and an energy of about 3.1 electron-volts (“eV”), when moving through a vacuum. By contrast, IR radiation may have a wavelength as long as about 100 micrometers (“μm”), with a frequency of about 3×10¹² Hz, and an energy of about 0.0124 eV, when moving through a vacuum. Though all light can be discussed with respect to any of the three related characteristics, generally high energy light is discussed with respect to energy, where relatively lower energy light is commonly discussed with respect to wavelength or frequency.

The term “substrate” used in the following description may include any supporting structure including, but not limited to, a semiconductor substrate that has an exposed substrate surface. A semiconductor substrate should be understood to include silicon, epitaxial silicon, silicon-on-insulator (SOI), silicon-on-sapphire (SOS), doped and undoped semiconductors, epitaxial layers of silicon supported by a base semiconductor foundation, and other semiconductor structures. When reference is made to a substrate or wafer in the following description, previous process steps may have been utilized to form regions or junctions in or over the base substrate or foundation. The substrate need not be semiconductor-based, but may be any support structure suitable for supporting the disclosed device, including, but not limited to, metals, alloys, glasses, natural and synthetic polymers, ceramics, fabrics, and any other suitable materials, as is known in the art.

As previously mentioned, it is desirable to create a single, two terminal, sensor that is sensitive to a large region of electromagnetic spectrum. A single sensor of this kind may be achieved by combining multiple materials that are each sensitive to different regions of electromagnetic spectrum. For example, a sensor that is sensitive to a large region of electromagnetic spectrum (“wide band sensor”) may be realized by stacking a plurality of materials in layers to form a single device that is sensitive to many smaller regions of electromagnetic spectrum that, in combination, encompass the larger region of electromagnetic spectrum of interest. This stacked wide band sensor may have the advantage of a small footprint.

The actual size of a region of electromagnetic spectrum that may sensed by a wide band sensor is relative and subjective. For example, the region of electromagnetic spectrum that is called visible light is very narrow when compared to the region of electromagnetic spectrum called infrared radiation. An embodiment of a wide band sensor according to this disclosure may be sensitive to multiple regions of electromagnetic spectrum within the “narrow” visible light region. As such, a wide band sensor may sense a narrow band of electromagnetic radiation or any suitable region of electromagnetic spectrum, as would be apparent to one of ordinary skill in the art given the benefit of this disclosure.

In another example, a wide band sensor may be achieved by fabricating a plurality of materials adjacent to each other, across the surface of a substrate, to form a single device that is sensitive to many regions of electromagnetic spectrum. Such a planar wide band sensor may have a larger device footprint than a stacked device, but may avoid one or more hurdles associated with a stacked wide band sensor. Additionally, a hybrid of the stacked and planar wide band sensor may be achieved by connecting a plurality of stacks of spectrum sensitive materials. Further, a plurality of wide band sensors may be fabricated in an array to create an array that may collect additional data points.

In some embodiments, a wide band sensor may comprise only two terminals, the terminals being connected to the first and last layers, respectively. The terminals of the wide band sensor may be configured to be further connected to a separate device or to circuitry within a monolithic device comprising the wide band sensor. The separate device or circuitry may be designed to measure one or more characteristics of the wide band sensor, such as, for example, the capacitance.

To achieve an operable stacked wide band sensor, regions of electromagnetic spectrum should be allowed to substantially penetrate the stacked layers of the sensor, to or through the last layer of the sensor. For example, by choosing materials that are substantially transparent to specific regions of electromagnetic spectrum, a stacked sensor may be achieved. The thickness of each layer of material may affect the transparency of the layer and may be selected to provide an advantageous light transmission or absorption characteristic.

Generally, when designing a stacked wide band sensor, it is desirable to arrange materials such that any light that is not absorbed by a layer is passed through to a successive layer, if present. Materials may be arranged such that the top most layer absorbs the highest energy light, while being substantially transparent to the rest of the light. The next layer may absorb a region of electromagnetic spectrum that has the next highest energy, and so forth until the last region of electromagnetic spectrum is absorbed or passed by the last layer of the stacked wide band sensor.

Considerations for choosing suitable materials, other than spectrum sensitivity and/or transparency, may include the cost and/or availability of materials, as well as the behavior of the material during fabrication. For example, both PbSe and PbTe are relatively inexpensive and plentiful materials that can be fabricated through evaporative deposition, which is a common and well-understood method. Other suitable materials would be apparent to one of ordinary skill in the art, given the benefit of this disclosure.

Additional fabrication methods that are suitable for manufacturing a wide band sensor may include physical deposition processes, such as RF sputtering, as well as chemical vapor deposition processes, including plasma enhanced chemical vapor deposition, and wet chemical and electrochemical deposition methods, among other suitable fabrication methods, as would be apparent to one of ordinary skill in the art, given the benefit of this disclosure. Further, differing fabrication methods used with a material may change one or more characteristics associated with the material, such as the sensitivity of the material to a region of the electromagnetic spectrum. Additionally, fabricating materials together in a stacked configuration may introduce defects that may need to be encapsulated to prevent oxygenation.

Materials suitable for use in a wide band sensor each have an inherent work function. A work function may be generally thought of as the amount of energy needed by an electron to move out of the material with which it is associated. When two materials with differing work functions are coupled, an interface is created at the boundary between the coupled pair of layers. The interface represents not only a physical change from one material to the next, but also represents the difference in work functions between the two materials. The difference in work functions at the interface may work to inhibit the transfer of carriers (electrons or holes) across the interface, creating an energy barrier that carriers must overcome in order to move from one material to the other. For example, a Schottky barrier may form when a semiconductor and a metal are coupled.

Alternatively, the difference between the work functions may have the opposite effect, allowing easy transfer of carriers across the interface. Thus, materials may be specifically selected to design an interface with advantageous properties regarding the mobility of carriers.

Each layer of a wide band sensor will have, at equilibrium, a population of electrons in the conduction band or conduction extended states and holes in the valence band or valence extended states. The number of majority and minority carriers is called the equilibrium number. When the wide band sensor is exposed to light, electrons are said to be generated, increasing the total number of electrons in the conduction band (or extended states). When a material has a number of electrons in excess of the equilibrium number, the material will be disposed to return to the equilibrium number electrons through recombination of electrons with holes in the valence band (or extended states). Thus, when excess carriers are no longer being generated, the material will return to equilibrium over time. The rate at which the material returns to equilibrium is a measurable and predictable rate.

The continuity equation for electrons, shown below, describes the number of electrons over time, and the recombination rate of a material.

∂n/∂t=(1/q)divJₙ+Gₙ−Uₙ

Where n=total number of electron carriers, q=charge, t=time, Jₙ is the electron current density, Gₙ is the generation rate, and Uₙ is the recombination rate for electrons. The recombination rate has a time constant term associated with it which is proportional to: ((n-n₀)/τ), where n₀=equilibrium concentration of carriers, and τ=carrier lifetime). The time constant term may determine one or more characteristics of the material, such as, for example, the capacitance. A similar equation can be written for hole carriers.

As can be seen in the continuity equation, carriers have a predictable recombination rate, Uₙ, that is associated with a material and environmental condition. Recombination occurs at a predictable rate independent from the generation rate of new majority carriers, Gₙ, and continues during and after the generation of additional majority carriers, until equilibrium is again reached.

The carrier recombination rate may affect suitable thickness ranges of selected materials. For example, if carrier recombination generally occurs at the surface of a specific material, the material may be designed to be relatively thin. For example, known suitable thicknesses of PbSe and PbTe may be about 1.4 μm and about 4.5 μm respectively. The thickness of materials can be optimized with respect to efficiency and noise reduction, as discussed by Piotrowski et al. in a paper entitled “Ultimate performance of infrared photo-detectors and figure of merit of detector material” and published in the 1997 periodical “Infrared Physics & Technology 38,” which is herein incorporated by reference in its entirety.

Additionally, the time constant associated with the recombination rate can be advantageously used when choosing materials for a wide band sensor. For example, the material used for one layer may have a long carrier recombination rate when compared to the carrier recombination rate of the material used for another layer. These varying recombination rates, if known, can be used to separate the contribution of each layer to a change in a characteristic of a wide band sensor as a whole.

As mentioned earlier, the intensity of incident light upon the sensor may affect the number of carriers seen within a specific layer, which will affect one or more measureable characteristics of the layer, such as the capacitance. Thus, a distinct region of electromagnetic spectrum and the intensity of this distinct region of electromagnetic spectrum may be measured by each layer of a wide band sensor. The output seen across terminals associated with the sensor contains all the information measured by the sensor. Further, the output may be separated, such as, for example, using deconvolution, into separate signals associated with each layer.

With the ability to differentiate the individual contributions of each layer comes the ability to specifically observe and/or specifically ignore contributions from each layer (i.e. the intensity of each region of electromagnetic spectrum). Thus, a system comprising a wide band sensor may process the output of the sensor to show only relevant results. The adapted output may be generated as quickly as the signal may be processed, which may be in substantially real time.

Additionally, the layers of the sensor may be chosen at the time of fabrication to be sensitive to only selected regions of electromagnetic spectrum. In this way, a wide band sensor may be designed to be inherently sensitive to only selected regions of electromagnetic spectrum.

As mentioned earlier, each layer has an inherent work function. This work function is related to the material of the layer, but also may be varied, such as through differing fabrication methods, among other variations, as would be apparent to one of ordinary skill in the art given the benefit of this disclosure. For example, materials that are coupled in a wide band sensor may be selected and fabricated such that a barrier to carrier movement is formed between materials. However, depending on the material and/or fabrication method, the barrier may function more as a minor impediment to carrier migration, or as a one way valve, than as a barrier.

A biasing potential may be applied across the terminals of a wide band sensor, to change the interface between the materials, for example, such that carriers generally do not cross the interface during operation. Additionally, a bias may encourage carrier collection at or near the interfaces of a wide band sensor. The bias may sweep electrons to one side of a layer and holes to the other side, and may impede the recombination of the electrons and the holes until the bias is removed, countered, or reversed.

Referring again to the continuity equation for electrons, the Jₙ term (electron current density) shows that a non-uniform density of electrons may affect the number of carriers over time. Thus, the movement of carriers to opposite sides of the layer, creating non-uniform densities of carriers within the material, may substantially lengthen the overall recombination time of the carriers after a bias is removed, countered, or reversed. This lengthening of time may enable a certain amount of customization of the number of majority carriers in a material over time, which may affect one or more measureable characteristics of the material.

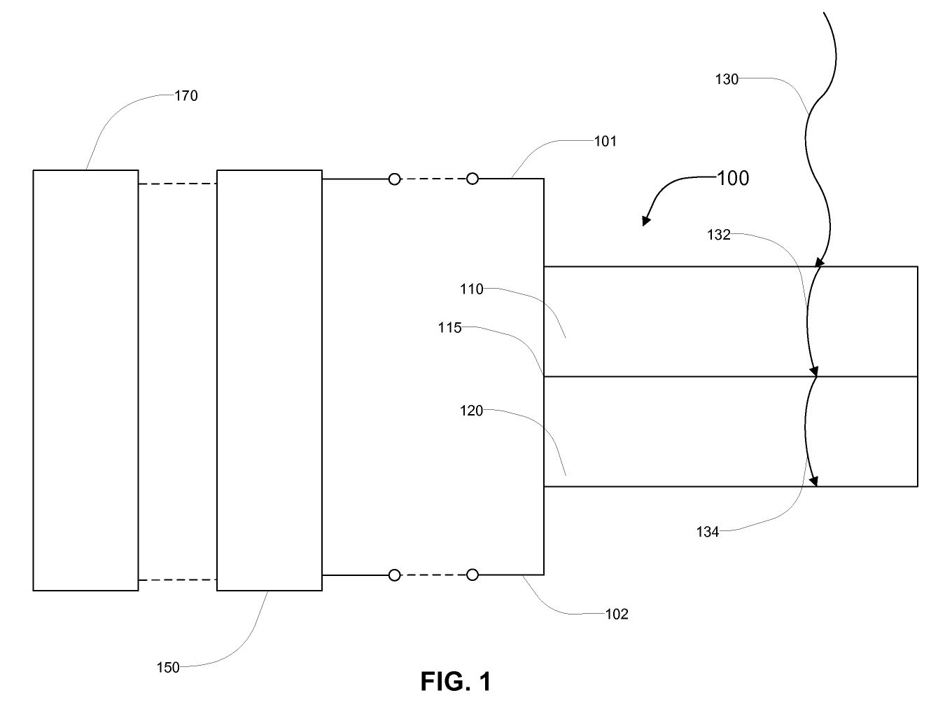

By way of example, a two layer stacked wide band sensor will now be described. FIG. 1 illustrates an embodiment of a stacked wide band sensor 100 comprising a first layer 110 and a second layer 120. The two layers, 110, 120 are coupled, creating an interface 115 between the layers 110, 120. Also shown is a first terminal 101 connected to the first layer 110, and a second terminal 102 connected to the last layer, which is the second layer 120 in this example.

Light 130 is incident upon an exposed surface of the first layer 110. The first layer 110 absorbs a portion of the light 130 and passes a first passed portion of light 132, to the second layer 120. The second layer 120 then absorbs a portion of the first passed portion of light 132 and passes a second passed portion of light 134. In other embodiments, the second layer 120 may substantially absorb the second passed portion of light 134, as would be apparent to one of ordinary skill in the art, given the benefit of this disclosure.

The stacked wide band sensor 100 illustrated in FIG. 1 may be designed to absorb different regions of electromagnetic spectrum from the incident light 130, for example, by selecting suitable materials during fabrication of the sensor 100. The first and second layers 110, 120 may comprise materials such as, for example, lead-selenide (PbSe), lead-telluride (PbTe), Indium Gallium Arsenide (InGaAs),Indium antimonide, mercury cadmium telluride, silicon, copper indium selenide, or copper indium sulfide. When suitable materials are combined, the stacked wide band sensor 100 will be sensitive to the regions of electromagnetic spectrum that are associated with the materials, enabling the sensor 100 to be sensitive to a wider band of spectrum than previously known sensors comprising only one material. The wide band sensor 100 also maintains a design where an output signal is seen at two terminals 101, 102, enabling relatively simple connection and output measurement.

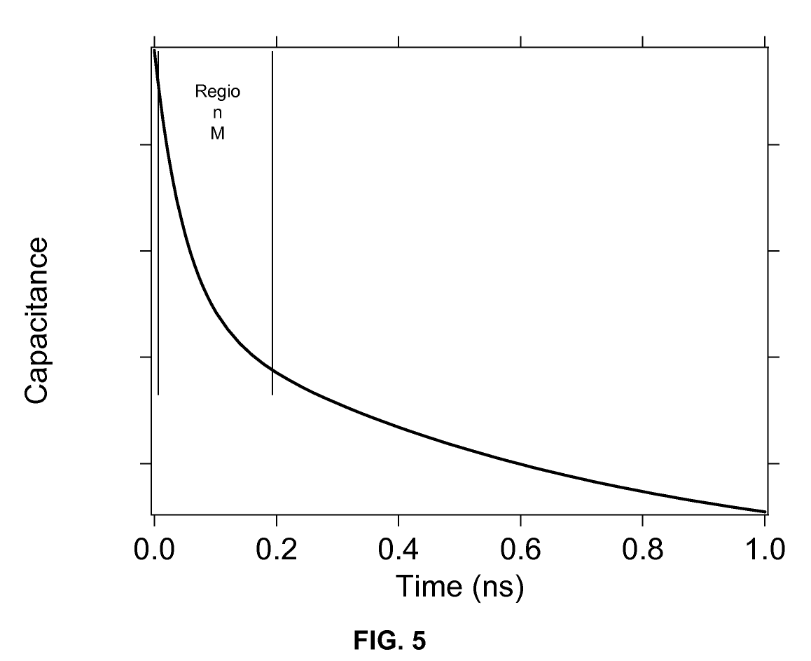

A measurement of a characteristic, such as, for example, the capacitance, of the sensor 100 over time can be seen as an output signal of the sensor 100, as shown in FIG. 5. The output signal of the sensor 100 can be seen and measured across the first and second terminals 101, 102 connected to the top-most and bottom-most layers, which corresponds to layers 110 and 120, respectively, in the embodiment shown in FIG. 1. The terminals 101, 102 may be connected to a characteristic measurement circuit 150 that is sensitive to changes over time with respect to one or more characteristics of the sensor 100, such as, for example, capacitance, charge, voltage, resistance, current, or another suitable characteristic of the sensor.

A signal separation module 170, such as a deconvolving module or other suitable hardware or software, may be used with embodiments of a wide band sensor 100 and/or characteristic measurement circuit 150. The signal separation module 170 may separate one or more contributions to the output signal that are attributable to one or more layers. The signal separation module 170 may be embodied in hardware by a general purpose microcontroller, microprocessor, FPGA, CPLD, PLA, PAL, or other suitable general purpose circuit, and may alternatively be embodied by an ASIC or other suitable application specific circuit, as would be apparent to one of ordinary skill in the art, given the benefit of this disclosure. Additionally, the signal separation module may be embodied by suitable software, or by a combination of hardware and software, as would be apparent to one of ordinary skill in the art, given the benefit of this disclosure. Alternatively, the output signal may be saved and manipulated at a later time by the signal separation module 170.

The two terminals 101, 102 of the wide band sensor 100 may be connected to a characteristic measurement circuit 150 that measures a characteristic such as capacitance as a function of time. Assuming the wide band sensor 100 has been exposed to a suitable spectrum of light for a sufficient amount of time to cause a build-up of carriers, the characteristic measurement circuit 150 may be activated to measure a change in capacitance of the wide band sensor 100 over time. During activation of the characteristic measurement circuit 150, a bias on the sensor may be added, removed, countered, or reversed. Additionally, the light source may be blocked or otherwise inhibited with respect to the wide band sensor 100 while the characteristic measurement circuit 150 is active.

The activated characteristic measurement circuit 150 may observe, for example, a relatively quick drop-off in capacitance, followed by a region of slower drop-off in capacitance, followed by another region of still slower drop-off in capacitance, and so on as illustrated by FIG. 5. Each change in capacitance may be interpreted as a contribution from one specific layer. Further, the signal as a whole can be separated to find the individual contributions from each layer by the signal separation module 170. The contribution from each layer corresponds to the intensity of the region of the electromagnetic spectrum that is transmitted to and absorbed by each layer. By contrast, existing sensors typically measure the electric current flow that is generated by a sensor when in the presence of light. Because electric current flows through all layers, it is difficult, if not impossible, to use electric current for measuring the characteristics of a layer of a multi-layer sensor such as the wide band sensor 100.

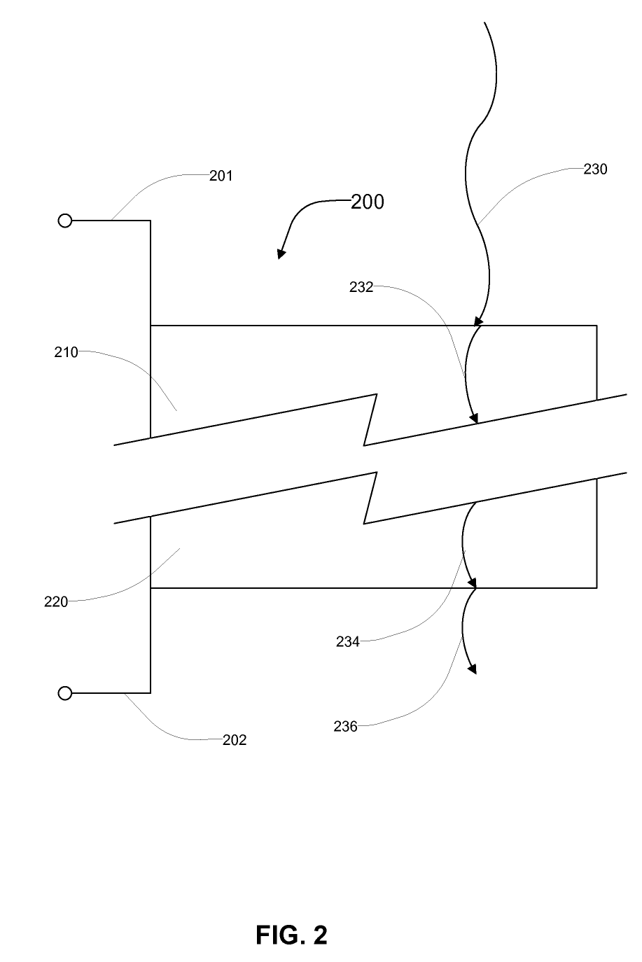

In the above example, a stacked wide band sensor 100 was described in terms of two layers. In other embodiments, a sensor with N-layers may be formed to measure N regions of electromagnetic spectrum. An N-layer embodiment of a stacked wide band sensor 200 is illustrated in FIG. 2. The sensor 200 comprises a first layer 210 connected to a first terminal 201 and an Nth layer 220 connected to a second terminal 202. One or more intervening layers (not shown) are located between the first layer 210 and the Nth layer 220. As illustrated in FIG. 2, the first layer 210 may be chosen such that it absorbs a portion of incident light 230 corresponding to a region of electromagnetic spectrum that has the highest relevant energy. The first layer 210 can be chosen such that it is substantially transparent to the light that is not absorbed, which is the passed light 232. The next layer (not shown) can be chosen to act similarly to the first layer 210, absorbing the next highest energy region of electromagnetic spectrum from the passed light 232, and being substantially transparent to the rest of the passed light 232. Additional layers may be chosen in the same manner. Finally, the Nth layer 220 can be chosen such that it absorbs a portion of the passed light (not shown) that is the least energetic of the incident light 230. The Nth layer 220 may be transparent to a remaining light 234 that is not absorbed. This remaining light 234 may move through the Nth layer 220 and out of the sensor 200, as illustrated by external light 236, or may pass to an absorptive layer (not shown) that will absorb the remaining light 234. Alternatively, the remaining light 234 may be fully or partially reflected back through the sensor 200, or may be absorbed fully or partially by the Nth layer 220.

As in the previous example, discussed with respect to FIG. 1, each of the layers, 210, 220, and intervening layers (if present), of the N-layer sensor 200 is coupled to a successive layer forming an interface (not shown). The interfaces of the N-layer sensor 200 behave similarly to the interface 115 (shown in FIG. 1), with respect to carriers. The discussion will not be repeated here.

Also, as explained previously, each layer, 210, 220, and intervening layers, of the sensor 200 may be chosen to be sensitive to a relevant region of electromagnetic spectrum, to have an advantageous work function, and to have an advantageous carrier recombination rate. Additionally, each layer can be chosen to be transparent to regions of electromagnetic spectrum to which the corresponding layer is not sensitive.

In operation, a bias may be applied across the terminals 201, 202, and thus across the layers, 210, 220, and intervening layers (if present), of the sensor 200 to prevent inter-material carrier movement and/or to encourage carrier collection at the interfaces. After a time, the bias may be removed, countered, or reversed, and a measurement circuit (not shown) may be activated to measure one or more characteristics of the sensor 200 over time. The measurement over time between the two terminals 201, 202, advantageously provides a single output signal. A characteristic measurement circuit 150 (shown in FIG. 1) may be connected to the terminals 201, 202 of the wide band sensor 200 to measure one or more characteristics of one or more layers of the sensor 200.

Due to differences in the carrier recombination rates of the materials, the contributions of each layer to the single output signal can be separated, differentiated, and/or deconvolved from the original single output signal. Further, the separated signals may be analyzed independently from or in combination with each other. A signal separation module 170 (shown in FIG. 1) may be used with the output signal of the sensor 200 to separate one or more contributions to the output signal that are attributable to one or more layers, as previously described (i.e. the signal separation module 170 may be configured to determine the individual contribution from each of a plurality of layers to an output signal).

As previously discussed, the output of the sensor 200 may be adapted such that specific regions of electromagnetic spectrum may be observed or ignored, as desired. Additionally, the sensor 200 may be designed and fabricated to specifically include or exclude materials that are sensitive to specific regions of electromagnetic spectrum.

Using a stacked wide band sensor 200 may enable measurement of a continuous region of electromagnetic spectrum ranging from RF to UV, which is measured as many smaller discreet regions of electromagnetic spectrum, in substantially the same area footprint as a sensor that measures a single discreet region of electromagnetic spectrum.

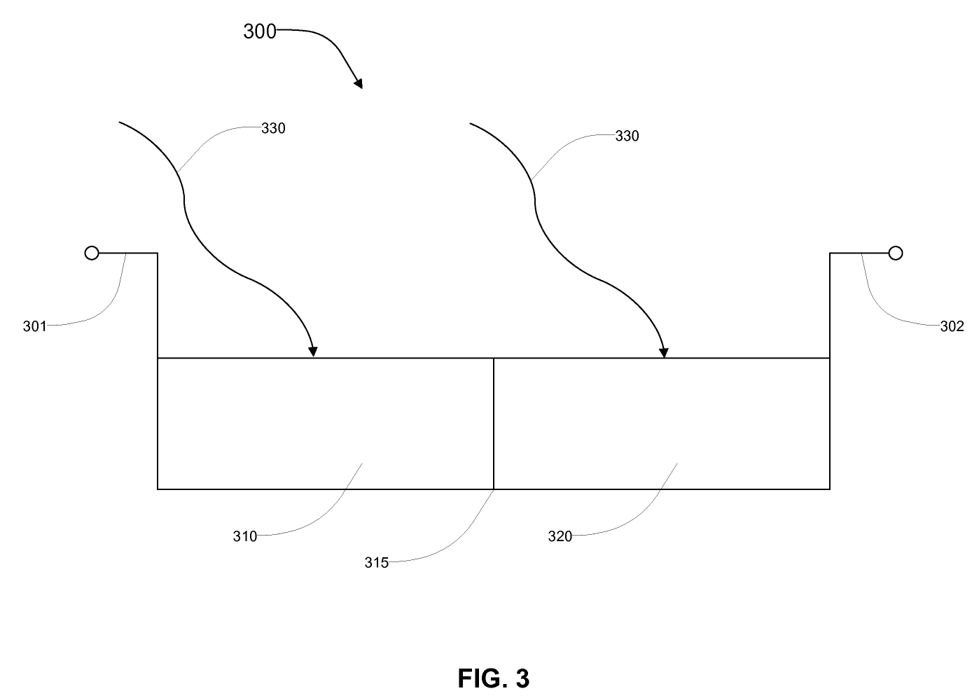

FIG. 3 shows another embodiment of a wide band sensor, a planar wide band sensor 300, comprising a first layer 310 that is coupled with a second layer 320, forming an interface 315 between the two materials. A first terminal 301 is connected to the first layer 310 and a second terminal 302 is connected to the last layer, second layer 320. As illustrated, the planar wide band sensor 300 may be fabricated across the surface of a substrate such that each layer is independently exposed to incident light 330.

As explained previously regarding stacked wide band sensors, materials suitable for a planar wide band sensor 300 may be selected to be sensitive to a relevant region of electromagnetic spectrum, may have varying work functions and may have varying carrier recombination rates. However, the materials selected for each layer 310, 320 of the planar wide band sensor 300 may be selected without regard to transparency. Additionally, the planar wide band sensor 300 may be expanded to include N-layers, as would be apparent to one of ordinary skill in the art, given the benefit of this disclosure.

Also, a characteristic measurement circuit 150 and/or a signal separation module 170 may be used with the sensor 300, as previously described.

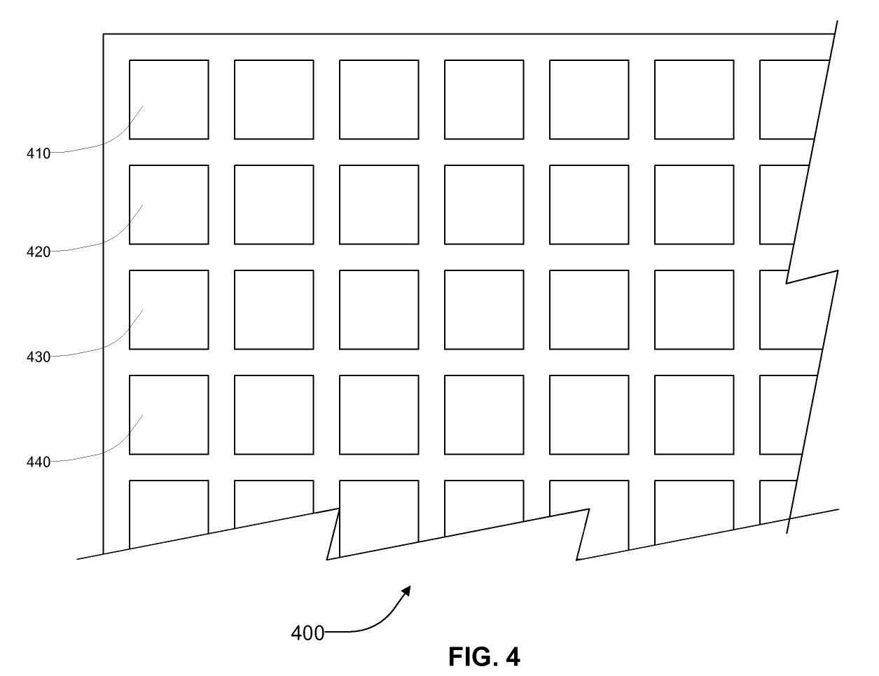

FIG. 4 is a top down view of a portion of a wide band array 400 comprising a plurality of wide band sensors, such as 410, 420, 430, and 440. For the sake of brevity, a representative selection of the wide band sensors 410, 420, 430, and 440, has been numbered and will be referenced. FIG. 4 is generally representative of an array of stacked wide band sensors, an array of planar wide band sensors and/or a combination of planar and stacked wide band sensors of similar or differing design. As described in previous embodiments, the wide band sensors 410, 420, 430, and 440, each comprise two terminals for connection and measurement purposes (not shown) and may be designed to be sensitive to a large region of electromagnetic spectrum. The array 400 may be comprised of identical wide band sensors, or alternatively, may be comprised of a mix of different wide band sensors that are designed to be sensitive to different regions of electromagnetic spectrum. For example, sensors 410 and 420 may comprise different materials and may be sensitive to different regions of electromagnetic spectrum. Alternatively, sensors 410 and 420 may comprise different materials and may be sensitive to substantially the same or overlapping regions of electromagnetic spectrum, providing additional data points. In the case that the sensors are designed to be different they still may form a repeating pattern across the array. For example, in the case that sensors 410 and 420 are different, sensors 430 and 440 may be substantially identical to sensors 410 and 420, respectively.

Each sensor 410, 420, 430, 440 of the array 400 may be connected to one or more characteristic measurement circuits 150 (shown in FIG. 1) and/or may be connected to one or more signal separation modules 170 (shown in FIG. 1).

The wide band array 400 may be fabricated on a substrate concurrently with additional circuitry. Alternatively, the array 400 may be fabricated separately from additional devices, and may be packaged separately from, or together with, the additional circuitry.

The wide band array 400 may be used, for example, to create an increased resolution dataset that may correspond spatially with focused light from a defined area. For example, the array 400 may be partnered with a set of optics that directs light onto the wide band array 400, creating a focal plane array. Further, the wide band array 400 may be fabricated with a micro-lens array to increase light collection efficiency. A wide band array 400 coupled with light directing devices may be used for a wide variety of applications, such as thermal imaging. The same array, if suitably designed, may be used, for example, to image a short band radio transmission location to show activity. Other uses and configurations would be apparent to one of ordinary skill in the art, given the benefit of this disclosure.

FIG. 5 shows an example output signal of a wide band sensor. This example output is a measurement of a characteristic of a wide band sensor over time, which may be measured by a characteristic measurement circuit 150 (shown in FIG. 1). For example, U.S. Pat. No. 5,532,955 to Gillingham and U.S. Pat. No. 6,067,062 to Takasu et al. disclose measurement devices that may be suitable to measure one or more characteristics of a wide band sensor and are both hereby incorporated by reference in their entirety.

The graph illustrated by FIG. 5 shows Time on the X-axis and Capacitance on the Y-axis. As shown in FIG. 5, the capacitance measured by the characteristic measurement circuit falls over time and there are distinct areas of movement with respect to the Y-axis illustrating the change in capacitance of a wide band sensor over time. For example, the change in capacitance denoted by Range M may be associated with the carrier recombination rate of an associated Layer M. The scale of the measured capacitance may range from femto-Farads to pico-Farads and may change with the design of a wide band sensor and an associated characteristic measurement circuit. In other embodiments, a different characteristic may be measured by the characteristic measurement circuit. Further, the sensor output signal may generate a different graph with different areas of movement, as would be apparent to one of ordinary skill in the art, given the benefit of this disclosure.

Although this invention has been described in terms of certain preferred embodiments, other embodiments that are apparent to those of ordinary skill in the art, including embodiments that do not provide all of the features and advantages set forth herein, are also within the scope of this invention. Therefore, the scope of the present invention is defined only by reference to the appended claims and equivalents thereof.

What is claimed is:

1. An electromagnetic radiation sensing system having a signal separation module connected to a sensor, the sensor comprising:
a first terminal;
a second terminal; and
a plurality of layers formed on a substrate, having at least a first layer and a last layer, the first layer being connected to the first terminal and the last layer being connected to the second terminal,
wherein each layer is coupled to at least one other layer to form an interface, each layer is sensitive to a distinct range of wavelengths of electromagnetic radiation, and each layer has a distinct carrier recombination rate,
wherein the sensor is configured to generate an output signal at the first and second terminals in response to electro-magnetic radiation incident upon a surface of the sensor, and
wherein the signal separation module is configured to determine the individual contribution from each of the plurality of layers to the output signal.

2. The system of claim 1, further comprising at least one interleaving layer positioned between the first layer and the last layer, the at least one interleaving layer being coupled to at least two other adjacent layers forming at least two interfaces.

3. The system of claim 1, further comprising a characteristic measurement circuit that is connected to the first terminal and the second terminal and is configured to measure capacitance, inductance, charge, voltage, resistance, or current, wherein the signal separation module is connected to the sensor through the characteristic measurement circuit.

4. The system of claim 1, wherein the plurality of layers are positioned in a stacked arrangement and wherein each layer is configured to be substantially transparent to electromagnetic radiation of lower energy than the range of wavelengths of electromagnetic radiation to which the layer is sensitive.

5. A sensor comprising:
a first terminal;
a second terminal; and
a plurality of layers formed on a substrate, having at least a first layer, a second layer, and a last layer, the first layer being connected to the first terminal and the last layer being connected to the second terminal,
wherein each layer is coupled to at least one other layer to form an interface, each layer is sensitive to a distinct range of wavelengths of electromagnetic radiation, and each layer has a distinct carrier recombination rate.

6. The system of claim 5, wherein at least one layer includes lead telluride, lead sulfide, indium gallium arsenide, lead selenide, indium antimonide, mercury cadmium telluride, silicon, copper indium selenide, or copper indium sulfide.

7. The system of claim 5, wherein at least one interface forms a Schottky barrier.

8. The system of claim 5, wherein the plurality of layers are each sensitive to a distinct, non-overlapping range of wavelengths.

9. A sensor array comprising:
a plurality of sensors arranged in an array across a substrate, each of the plurality of sensors being connected to one or more characteristic measurement circuits and comprising:
a first terminal,
a second terminal, and
a plurality of layers, having at least a first layer and a last layer, each layer being coupled to at least one other layer forming an interface, each layer being sensitive to a distinct range of wavelengths of electromagnetic radiation, and having a distinct carrier recombination rate, the first layer being connected to the first terminal and the last layer being connected to the second terminal.

10. The array of claim 9, wherein each of the plurality of sensors are configured to be substantially the same.

11. The array of claim 9, further comprising a micro-lens array.

12. The array of claim 9, wherein the sensor array is configured to be used with a set of optics.

13. A method of detecting a range of wavelengths of electro-magnetic radiation, the range having a plurality of distinct sub-ranges, the method comprising:
exposing a sensor to electro-magnetic radiation, the sensor having a plurality of layers, each layer being coupled to at least one other layer to form an interface and being sensitive to a distinct sub-range of wavelengths of electro-magnetic radiation, the sensor having a first terminal connected to a first layer and a second terminal connected to a last layer;
measuring one or more characteristics of the sensor over time to generate an output signal at the first terminal and the second terminal;
determining the individual contribution to the output signal from each of the plurality of layers.

14. The method of claim 13 further comprising applying a voltage bias to the sensor across the first and second terminals.

15. The method of claim 14 further comprising removing the voltage bias prior to measuring one or more characteristics of the sensor.

16. The method of claim 13, further comprising outputting the determined individual contributions from each of the plurality of layers.

17. The method of claim 13, further comprising outputting a selected portion of the determined individual contributions.

18. The method of claim 13, further comprising generating carriers in at least one layer when the sensor is exposed to electro-magnetic radiation.

19. The method of claim 18, further comprising allowing the generated carriers to recombine within the same at least one layer in which they were generated.

20. The method of claim 13, further comprising collecting the carriers at at least one interface.
